(19) United States
(12) Patent Application Publication
(10) Pub. No.: US 2020/0090425 A1
(43) Pub. Date: Mar. 19, 2020

(54) USING VEHICLE ELECTRICAL SYSTEM MONITORED VALUES

(71) Applicant: Cambridge Mobile Telematics Inc., Cambridge, MA (US)

(72) Inventors: Schuyler Senft-Grupp, Los Angeles, CA (US); Lewis Girod, Arlington, MA (US); Hari Balakrishnan, Belmont, MA (US); William Bradley, Arlington, MA (US)

(21) Appl. No.: 16/134,099

(22) Filed: Sep. 18, 2018

(51) Int. Cl. G07C 5/04; G01R 31/36; G07C 5/08; G07C 5/00

(52) U.S. Cl. CPC G07C 5/04; G01R 31/3648; G07C 5/008; G07C 5/0816; G07C 5/0808; G01R 31/3689

(57) ABSTRACT

Among other features, a time series of values of an electrical parameter of an electrical system of a vehicle is accessed. An event or a state of the vehicle is determined based on the time series of values of the electrical parameter. The event or state is communicated to an occupant of the vehicle or to a third party.

### BACKGROUND

This description relates to using vehicle electrical system monitored values.

Some telematics systems and other devices measure battery voltage to determine battery health. See, for example, Method and System for Predicting Battery Life Based on Vehicle Battery, Usage, and Environmental Data, United States patent publication 2011/0082621 A1. For more information about the user of telematics systems for vehicles, see, for example, System and Method for Obtaining Vehicle Telematics Data, United States patent publication 2015/0312655 A1, incorporated here by reference in its entirety.

### SUMMARY

In general, in an aspect, a time series of values of an electrical parameter of an electrical system of a vehicle is accessed. An event or a state of the vehicle is determined based on the time series of values of the electrical parameter. The event or state is communicated to an occupant of the vehicle or to a third party.

Implementations may include one or a combination of two or more of the following features. Accessing the time series of values includes accessing a time series of voltages of a battery connected to the electrical system. Determining of the event or state includes determining the event or state based on historical streams of values of the electrical parameter and known corresponding events or states. The communicating of the determined event or state includes communicating the determined event or state to the occupant of the vehicle through a user interface of a mobile device. The communicating of the determined event or state includes communicating the determined event or state to a third party remote from the vehicle. Values of a parameter other than of the electrical system of the vehicle are accessed. The other parameter includes a time, a location, an acceleration, a route, a gear level, or a temperature. The monitor identifies a circumstance involving the vehicle or an occupant of the vehicle based on the values of the electrical parameter and the values of the other parameter. The circumstance involves at least one of convenience, risk, safety, maintenance, and driver behavior. The circumstance includes at least one of headlights and ambient light, battery drainage, an unlocked vehicle, a window left open, transmission performance, turn signal usage, and distance traveled.

In general, in an aspect, a method includes measuring a series of values of a voltage at the terminals of a battery of a vehicle, determining an event or a state of the vehicle based on the measured series of values and on known events or states associated with historical series of values of voltages at terminals of batteries of one or more vehicles, based on at least the determined event or state, identifying a circumstance involving the vehicle or a driver of the vehicle, and reporting the circumstance to the driver of the vehicle or to a third party.

Implementations may include one or a combination of two or more of the following features. The known events or states and the associated historical series of values include fingerprints. The determining of the event or state of the vehicle includes correlating the fingerprint as a matched filter with time windows of the measured series of voltage values. The correlating of the fingerprint as a matched filter includes correlating with time shifted versions of time windows of the measured series of voltage values. The correlating of the fingerprint as a matched filter includes de-biasing time window of the measured series of voltage values. The determining of the event or state of the vehicle includes using a hidden Markov model. The determining of the event or state of the vehicle includes applying the measured series of voltage values to a classifier. The event or the state of the vehicle includes one or more of: vehicle engine turned on, vehicle engine turned off, headlights turned on, headlights turned off, turn signal on, power windows used, power locks used, excess vehicle battery power drain when vehicle is off, and vehicle steering occurred. The circumstance is associated with one or more of: convenience, risk, safety, maintenance, and driver behavior. The circumstance includes at least one of headlights and ambient light, battery drainage, an unlocked vehicle, a window left open, transmission performance, turn signal usage, and distance traveled. Reporting the circumstance includes presenting an alert through a user interface of a mobile device. The event or state is determined by an app running on a mobile device. The circumstance is identified by an app running on a mobile device. The event or state is determined by a server remote from the vehicle. The circumstance is identified by a server remote from the vehicle. The identifying of the circumstance is based also on data derived other than from the terminals of the battery of the vehicle. The data includes at least one of a time, a location, an acceleration, a route, a gear level, or a temperature.

In general, in an aspect, an apparatus includes a monitor including a processor and a memory to store instructions executable by the processor to cause the monitor to (a) access a time series of values of an electrical parameter of an electrical system of a vehicle, (b) determine an event or a state of the vehicle based on the time series of values of the electrical parameter, and (c) communicate the determined event or state to an occupant of the vehicle or to a third party.

Implementations may include one or a combination of two or more of the following features. The monitor accesses a time series of voltages of a battery connected to the electrical system. The monitor to determines the event or state based on historical streams of values of the electrical parameter and known corresponding events or states. The monitor includes an app of a mobile device in the vehicle. The monitor includes a server. The monitor communicates the determined event or state to the occupant of the vehicle through a user interface of a mobile device. The monitor communicates the determined event or state to a third party remote from the vehicle. The monitor accesses values of a parameter other than of the electrical system of the vehicle. The other parameter includes a time, a location, an acceleration, a route, a gear level, or a temperature. The monitor identifies a circumstance involving the vehicle or an occupant of the vehicle based on the values of the electrical parameter and the values of the other parameter. The circumstance involves at least one of convenience, risk, safety, maintenance, and driver behavior. The circumstance includes at least one of headlights and ambient light, battery drainage, an unlocked vehicle, a window left open, transmission performance, turn signal usage, and distance traveled. The monitor provides a report or alert of the circumstance. The monitor includes a sensor configured to sense the values of the electrical parameter of the electrical system of the vehicle and provide them for access by the monitor. The sensor is configured to provide values of the electrical parameter for access by the monitor at a rate lower than the rate at which the sensor senses the values. The sensor is configured to provide the values wirelessly for access by the monitor. The sensor is electrically connected to the electrical system of the vehicle. The monitor provides the report or alert through a user interface of the monitor.

In general, in an aspect, an apparatus includes a connector configured to be coupled electrically to an electrical system of a vehicle, circuitry configured to sense a time series of values of an electrical parameter appearing at the connector, a processor configured to process the series of values to produce information about the series of values of the electrical parameter, the produced information being indicative of a state or event of the vehicle, and a communication component configured to send the produced information wirelessly to a mobile device in the vehicle.

Implementations may include one or a combination of two or more of the following features. The time series of values of the electrical parameter include a time series of voltages of a battery connected to the electrical system. The produced information includes values of the electrical parameter appearing at a rate lower than the rate at which the time series of values are sensed.

These and other aspects, features, and implementations (a) can be expressed as methods, apparatus, systems, components, program products, methods of doing business, means or steps for performing a function, and in other ways, and (b) will become apparent from the following descriptions, including the claims.

### DESCRIPTION

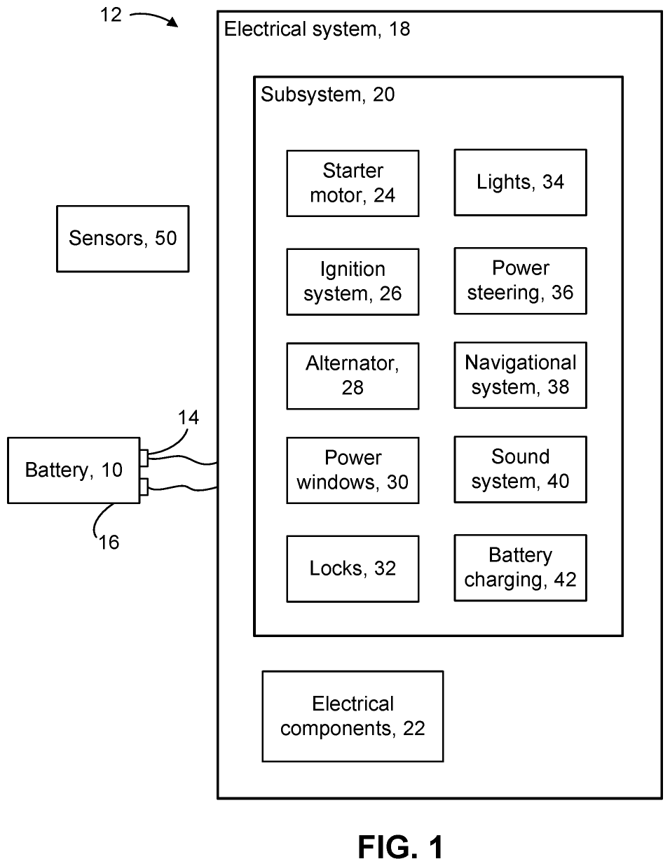

FIGS. 1, 2 and 7 are block diagrams.

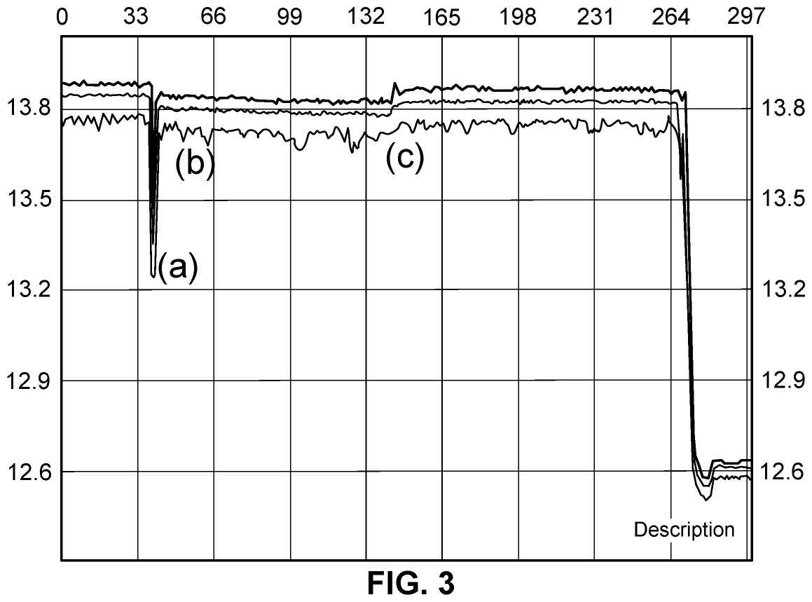

FIG. 3 is a graph.

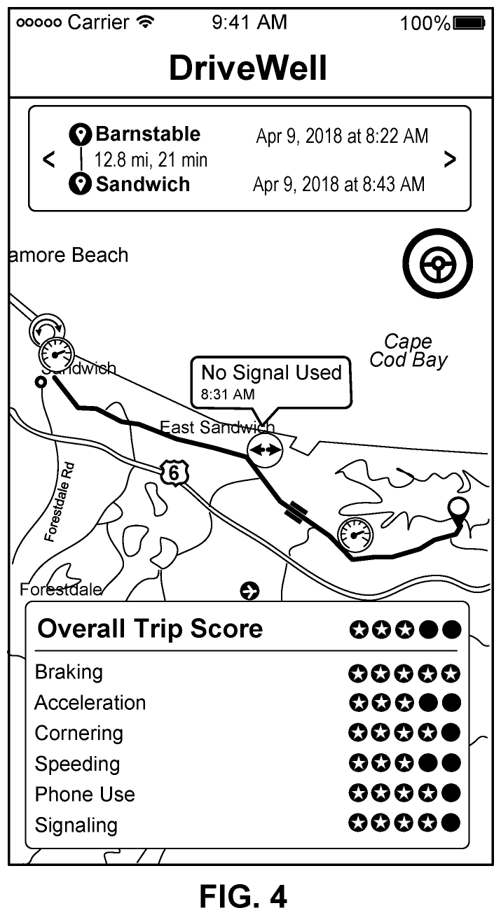

FIGS. 4, 5, and 6 are screen shots.

Automobiles and other vehicles are complex systems of interrelated mechanical and electrical subsystems and components operated under both automatic and human control. The state of each of the components and subsystems and of a vehicle as a whole can be characterized based on values of parameters. The state can represent the static condition or the functional condition of a component, a subsystem, or a whole vehicle and can sometimes indicate current or future problems. When considered in combination with other information (such as time or location), a circumstance of interest (for example, that head lights should be turned at dusk) can be determined. Sensing, monitoring, identifying, determining, and reporting such states can be useful to the driver, maintenance providers, and other parties who can make use of information related to safety, security, operation, risk, status, and maintenance of the components, the subsystems, and the whole vehicle.

For some vehicles, parameters from which such states and circumstances can be derived are available through an OBD-II data port, but some parameters may be accessible only to the vehicle manufacturer or may otherwise not be directly reported. Typically, each vehicle make and model has its own codes for expressing the parameters and the codes are often proprietary, making it difficult or impossible for any party other than the manufacturer or parties authorized by the manufacturer to read and use the parameter values.

Mobile telematics systems, which are sometimes used to measure vehicle parameters, are often OBD-II devices, affixed “black box” hardware, smartphones, or combinations of them. These mobile telematics systems usually measure raw parameters, such as time, location, speed, and acceleration.

We use the term “vehicle” broadly to include, for example, any motorized conveyance, including any such conveyance that uses a battery for any operating purpose. Vehicles can include cars, trucks, motorcycles, scooters, and boats, for example.

We use the term “vehicle state” or simply “state” broadly to include, for example, any aspect of the static condition or functional condition, character, status, or quality of a component or subsystem of a vehicle or of a vehicle as a whole, and in particular any such aspect that is variable or changeable. Vehicle state can refer, for example, to any component or subsystem of the vehicle that can be on or off, engaged or not engaged, open or closed, or have an aspect that is variable over a range. In some cases, we use the term “vehicle state” to refer to a complete vehicle state taking account of values of some or all parameters for some or all aspects of the vehicle state. A vehicle state changes whenever there is a change in any of the parameters.

We use the term “vehicle event” or simply “event” broadly to include, for example, any change in a vehicle state, such as powering a vehicle, turning on the ignition, turning headlights on or off, or locking or unlocking vehicle locks, to name a few.

We use the term “parameter” broadly to include, for example, any variable whose value is indicative of any aspect of a vehicle state.

Here we describe a technology (the “technology”) that, among other things, monitors electrical parameters at a vehicle battery or at other locations in a vehicle's electrical system and uses the information obtained by the monitoring to determine and report static states, functional states, and events of components and subsystems of the vehicle or the vehicle as a whole and circumstances related to such states.

We use the term “monitor” broadly to include, for example, sense, measure, identify, observe, detect, scan, or track.

We use the term “electrical parameters” broadly to include, for example, voltage, current, resistance, capacitance, power, or charge, among others.

We use the term “electrical system” broadly to include, for example, a set of electrical components that use, supply, process, conduct, or convert electricity. An electrical system of a car, for example, includes a battery, wires, lights, an alternator, a distributor, audio components, sensors, motors, and other components.

In some examples, the monitoring entails measuring voltage at a car battery using a voltage sensor, transmitting data representing the measured voltage wirelessly to a smartphone where the data can be analyzed to determine the vehicle state, a vehicle event, or a circumstance, and report it directly to the user of the smartphone. In some cases, the data or the state, event, or circumstance can be transmitted wirelessly to a data server or another device for storage, analysis, or reporting.

As shown in FIG. 1, the battery 10 of a vehicle 12 is connected through its positive and negative terminals 14, 16 to the vehicle's electrical system 18 and the electrical system's electrical subsystems 20 and electrical components 22. Typically, the electrical components and electrical subsystems consume electrical energy and convert it to other forms of energy, such as mechanical, light, heat, or sound energy or use small amounts of electrical energy for sensing or controlling other components. The electrical energy consumed by these components is provided by the battery when the engine is not running, or by the alternator when the engine is running. In some cases when the electrical load of components that are consuming electrical energy cannot be supplied by the alternator some of the load is provided by the battery. At times when the battery is not needed to serve part of the load, the alternator supplies electrical energy to the battery to recharge it.

The electrical components of the electrical system of a vehicle such as a car can include a starter motor 24, an ignition system 26, the alternator 28, power windows 30, locks 32, lights 34, electric-assist and electric power steering 36, a navigational system 38, a sound system 40, and a battery charging system 42, among others.

The number and identity of the electrical components and subsystems that the battery is powering at a given time and for periods of time vary depend on a variety of factors including which components or subsystems are turned on or off or are operating at particular levels, the functions that each component or subsystem is performing, the static condition or functional condition of the component or subsystem, and the nature of its electrical behavior relative to and in interaction with the battery that is supplying its power. Each of the electrical components and electrical subsystems exhibits values for electrical parameters from time to time based on such factors.

The battery in turn exhibits values for electrical parameters (such as voltage) from time to time that depend not only on its own operation but also depend on and have complex relationships with the electrical parameters exhibited by the electrical components and electrical subsystems of the electrical system and also with ambient conditions such as temperature or altitude or location of the vehicle. Because of these dependencies and complex relationships, by measuring and processing information about the electrical parameters of the battery, it is possible to determine the static states and functional states of the electrical components, subsystems, and the overall vehicle. The components and subsystems of the electrical subsystems are interconnected by wires and cables and in some cases are networked by wires and cables. As a result, at least some of the static states and functional states of the components can be detected at a variety of locations in the electrical system, in particular at the battery terminals or locations that are wired directly to the battery terminals.

A wide variety of static states and functional states of components and subsystems of the electrical system of a vehicle can be detected, including, for example: the on or off state; connected or not connected; operating or not operating; wear state or other state associated with age or usage; rate of operation; expected failure; current features being used or requested or implemented; performance relative to expected performance; and others; and combinations of them.

As shown in FIG. 1, in some implementations of the technology, one or more sensors 50 are connected to sense electrical parameters of the battery 10. The sensors can be connected directly to one or more of the terminals 14, 16 of the battery or can be coupled to the electrical system of the vehicle at another location where measurement of electrical parameters, for example, will be indicative of the electrical parameters at the terminal of the battery or of one or more of the components or subsystems of the electrical system. For example, the coupling of the sensors could occur at other locations along wires or cables that are directly connected to the battery terminals. In some instances, it may be possible to couple the sensors to other components and at other locations of the electrical system of the vehicle that are not directly connected to the battery terminals.

In some examples, an electrical parameter measured by the sensor is the voltage across the terminals of the battery. In some cases other electrical parameters could be measured, such as current, power, resistance, capacitance, or others, and combinations of them.

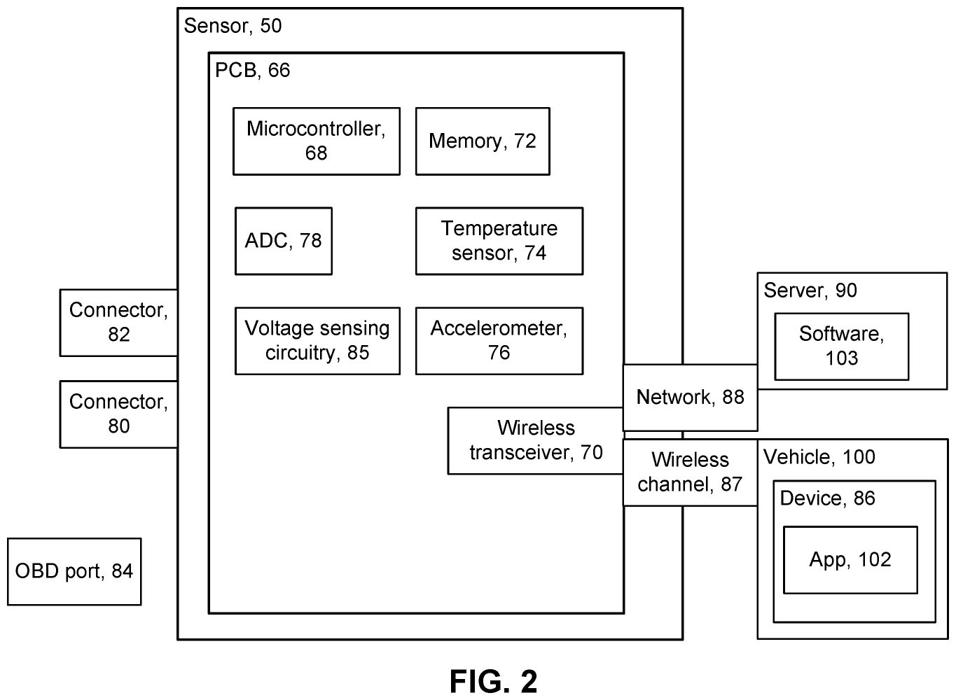

As shown in FIG. 2, in some implementations, a sensor 50 of the technology is a discrete device that is added temporarily or permanently to the vehicle and includes a printed circuit board 66, a microcontroller 68, a wireless transceiver 70, a memory 72, a temperature sensor 74, an accelerometer 76, and analog-to-digital conversion (ADC) circuitry 78. The sensor includes two wire connectors 80, 82 that, in some cases, connect directly or indirectly to the battery's positive and negative terminals. These connectors can connect either directly to the battery at its terminals using a mechanical connection (e.g., bolts, spring clips, or direct soldering), or through another access point, such as an OBD-II port 84. In the non-direct-battery connection case, the wires connected to the wire connectors 80, 82, terminate in the appropriate mating connector.

In some implementations, the sensor's main function is to sense, for instance, the voltage across the terminals of the battery. The microcontroller manages the behavior of the sensor and performs low-level signal processing of the voltage sensed by a voltage sensing circuitry 85 across the terminals of the battery. Among other things, the microcontroller controls the rate of battery voltage measurements, reads the battery voltage using the ADC, reads data from the accelerometer and the temperature sensor, and stores these measurements and system log files in the memory. The battery voltage can be measured at a variable rate depending on the type and frequency of state changes of electrical components, electrical subsystems, or the vehicle as a whole, as discussed later. For many state changes (events) a measurement rate of 100 Hz is sufficient although in some cases it may be useful to sample at a higher rate, for example, to measure engine RPMs, which may require a minimum measurement rate of 20 kilohertz. In other situations a lower rate may be sufficient, for example, measuring the activation of the headlights. The microcontroller can dynamically scale the measurement rate as needed. The measurement rate can differ for different components of the sensor. For example, the accelerometer data can be measured at a rate of 100 Hz. Temperature data can be measured at 1 Hz or less frequently.

The stored data for the electrical (e.g., the voltage) and other (e.g., the acceleration) parameters can be transmitted wirelessly through a wireless channel 87 to one or more other devices 86 (such as a mobile phone) or through a network 88 to a server 90 (e.g., a remote server) for further processing and storage. Various protocols can be used for wireless transmission including: (1) directly to a mobile phone (mobile device) or other Bluetooth receiver over Bluetooth Low Energy (BLE), (2) to a networked server over a low power wide-area network (e.g. Sigfox, LoRa), or (3) to a networked server over standard cellular mobile networks used by smartphones.

Among other functions, the sensor microcontroller can perform signal processing to reduce the rate at which the data is communicated to the other devices or server from a higher raw rate at which the sensor measurements are taken to a lower rate that meets bandwidth limitations of the wireless transfer mode. For this purpose, the microcontroller analyzes successive chunks of the data to be communicated. A typical payload chunk size may be 251 bytes in some protocols. Each chunk comprises a time series of data, and the microcontroller calculates summary statistics about the data of each chunk. The output of this analytical process can include down-sampled data, mean and standard deviation values, maximum and minimum values, and frequency content of the original data. The frequency content can be calculated using a fast Fourier transform.

When possible, the sensor 50 transmits reduced rate data directly over BLE to a smart phone or other mobile device 86 of a driver or other occupant of the vehicle 100, for example. The mobile device can be running a mobile telematics app 102 that has a variety of functions in addition to handling the battery parameter data, or it can be dedicated specifically to the handling of such data. In some implementations, the data transmitted to the mobile device can include time-stamps, battery voltage or other electrical parameters from the battery or the electrical system and related signal statistics, temperature, acceleration, and system log information. We sometimes refer to the time series of each of the types of data as a stream. The mobile telematics app considers one or more of these data streams in conjunction with or in combination with other data streams it is collecting from internal sensors or from other sources (e.g., GPS location, speed, coarse location from wifi or cell tower, rotation indicated by a gyroscope, accelerometer, barometer, magnetometer, date, time, and system log information).

In some cases, the battery voltage data (e.g., battery voltage parameter values) is analyzed locally in real time on the smartphone to identify vehicle states or vehicle events and in some cases circumstances related to such states or events. In some implementations, the real time data processing is achieved by matching the continuous battery voltage data stream to predefined continuous battery voltage fingerprints.

We use the term “fingerprint” or “exemplar vector” broadly to include, for example, any set of parameter values that can be correlated with one or more corresponding states or events. In some cases a fingerprint is developed by analysis of historical sequences of parameter values and known corresponding states or events. In some cases a fingerprint can be defined by one or a combination of any two or more of the following features of the historical sequences of parameter values (which we sometimes call a “signal”): relative or absolute signal; relative or absolute rate of change in the signal; the frequency of the signal; or the shape of the signal; or others. In some examples, fingerprints are generated by collecting baseline historical data from a particular vehicle (the same vehicle for which the fingerprints will be applied in real-time); one or more other vehicles, or combinations of them. The collected baseline data can be processed using machine learning algorithms or other techniques as described later. Unique fingerprints can be generated for each type of parameter that is monitored in real-time (e.g. a fingerprint for engine start, a fingerprint for headlights, etc.).

The battery voltage data stream and other data streams for other types of data captured by the sensor smartphone (including speed, acceleration, location, and time, and corresponding vehicle states and events determined by processing performed on the mobile device) can be uploaded wirelessly through the cellular network to a remote server for additional processing. In some cases, for example, when the sensor cannot connect wirelessly to a smartphone at the vehicle, the sensor may transmit one or more of the data streams it has collected to the server through other wireless channels.

The results of the real time data stream analysis performed at the mobile device (e.g., the use of fingerprints to identify vehicle states and events) can be used to alert the driver or other occupant of the vehicle (or other parties as mentioned earlier) to any immediate or other safety, security, or other circumstance associated with the current vehicle state. In some cases, nearly real-time processing and alerting can be done by and from the remote server through the mobile device at the vehicle. Additional processing of the data streams can be done later on a remote server for a variety of purposes. For example, such processing can identify trends in behavior of each driver or of groups of drivers that may be correlated to increased risk, such as pairing driving behaviors with subsequent insurance claims to identify dangerous behaviors; pairing driving behavior or vehicle characteristics with automotive repair expense reports to identify early causes or indicators of vehicle failure; tracking driving behavior within a fleet of vehicles (e.g., delivery trucks) to identify which vehicles are most in need of repair. Or historical data sequences can be analyzed to identify chronic maintenance issues that should be addressed.

The technology's ability to identify and report states, events, and circumstances of vehicles at given times and over time can enable a wide variety of applications useful for a range of different parties. In some applications, the derived information about vehicle states can be supplemented with other data streams (for example, telematics data streams).

In the examples given below, circumstances determined based on battery voltage data streams combined with additional telematics data streams can be categorized based on the type of resulting benefit or goal: (1) correcting unsafe driving conditions, (2) reducing insurance risk, (3) teaching safer driver practices, (4) alerting about maintenance needs, and (5) improving convenience, among others, and combinations of them.

In some implementations, the technology can analyze the vehicle's battery voltage data stream at a moment in time or its profile over a period of time to detect vehicle events or vehicle states or circumstances.

The app running on the mobile device or software running on a remote server, or both, can include an event detector for detecting vehicle events based on the data streams, a state detector for detecting vehicle states based on the data streams, or a circumstance detector for detecting circumstances related to vehicle states and events.

An illustration of the voltage behavior associated with several example events is provided by FIG. 3. In the figure the example events are (a) headlights turned on, (b) power windows used, (c) headlights turned off, and (d) car turned off. We describe several methods of event detection. Throughout, we assume that battery voltage is being sampled regularly and the battery voltage data stream is provided to the event detector. We describe the following in terms of the event detector; the analysis for a state detector is analogous. The methods discussed below can be used individual or combined in some cases.

First method: We collect a window W of several seconds of voltage samples of the battery voltage data stream. We have constructed an exemplar vector (i.e., a fingerprint) of historical voltage samples corresponding to an event of interest. We use the exemplar vector as a matched filter and correlate it with the samples of the window W. If the correlation exceeds a given threshold, we determine that the event has occurred. W is then advanced by a portion of the window length and the process is repeated. W can also be shaped by a windowing function (such as a Hann or Hamming window) to minimize edge effects in the correlation. A single event may have more than one exemplar vector. The constructed exemplar vectors are associated, for example, with corresponding makes and models of vehicles. For matching, the relevant exemplar vector(s) can be found by matching the make and model of vehicle with the vehicle from which the current data stream was obtained, or by choosing a similar vehicle(s), or by considering an alternate set of vehicles, such as all of them.

Second method: We proceed as with the first method, except we replace the correlation step as follows: We consider each possible shift of the exemplar vector in time relative to the window W of the data stream, subtract the data at one position of W from the shifted position of W, and consider the difference. We compute a metric of the difference, such as the sum of the squared differences. We determine an event if the metric is below a given threshold.

Third method: It can be helpful to de-bias the data stream (the signal) for window W before correlation, as the time-based change in the signal may be more characteristic than the absolute signal. To that end, we collect a window W of several seconds of voltage samples of the data stream, and then apply a moving median filter. We select the size of the median window to be longer than the expected event. The moving median filter produces some output M. We subtract the two signals to produce a new signal D=W−M. We then apply the first or second method to D.

Fourth method: In some implementations a method of de-biasing the signal is to estimate the derivative. To that end, we can apply, e.g., a Savitzky-Golay filter to both smooth the data and estimate the first or second derivative. For example, the event of “turning on headlights” produces an extremely large second derivative of the smoothed signal.

Fifth method: We can construct a hidden Markov model, whose hidden states correspond to the vehicle states. We recover the parameters to the hidden Markov model through the Expectation-Maximization algorithm. Given a corpus of voltage data streams with events labelled, we can correlate the events with the hidden states. Given a new signal (voltage data stream), we perform inference on its voltage levels. We take a sum of the probabilities of the hidden states, weighted by correlation; when this sum exceeds a threshold, we determine that an event has occurred. The data for this method can also be de-biased before use, as described in the third and fourth methods. This method can be performed across all vehicles, across particular makes and models of vehicles, or the make and model can be given as an input to the hidden Markov model.

Sixth method: Given a sufficient corpus of voltage data with labelled events, we can use a classification technique (such as a recurrent neural net) to predict directly the presence or absence of an event. This method can be performed across all vehicles, across particular makes and models of vehicles, or the make and model can be given as an input to the classifier.

The outputs of the event detector, the state detector, and the circumstance detector include information about the occurrence of an event or state or circumstance, the time of occurrence, the probability of and/or confidence in the occurrence, and the identity of the event or state or circumstance. The outputs can be computed within the app (at the mobile device) or the software (at the remote server) and enable other processes in the app or software to know if an event, state, or circumstance has occurred and which event, state, or circumstance has occurred (e.g., if the car engine has been turned on or off). In some cases, the voltage samples can also be uploaded to a server, processed remotely, and summaries of the events can be returned to the app on the mobile phone.

A wide variety of vehicle events, states, and circumstances can be detected using the battery voltage sensor data and one or a combination of two or more of the analytical methods described above or other methods. Among the detectable vehicle events are the following (and combinations of them): vehicle engine turned on, vehicle engine turned off, headlights turned on, headlights turned off, turn signal on, power windows used, power locks used, excess vehicle battery power drain when vehicle is off, and vehicle steering occurred (this is available in cars with electro-hydraulic and electronic power assist).

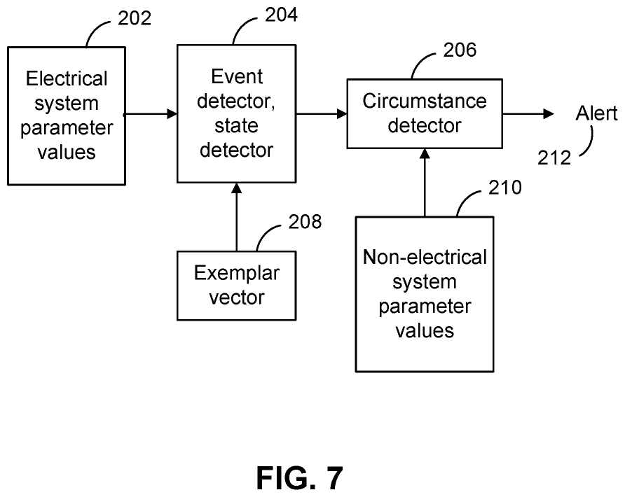

Thus, as shown in FIG. 7, the event detector and state detector 204 can use electrical system parameter values 202 and exemplar vectors 208 to determine states and events, and a circumstance detector 206 can use the states and events together with non-electrical-system parameter values to determine circumstances and provide corresponding alerts 212.

The technology offers at least the following benefits and advantages. The technology is unique in its ability to identify and report certain vehicle states, vehicle events, and vehicle circumstances such as headlight status, power window use, power door lock use, turn signal usage, and transmission health. The technology can link these vehicle states, events, and circumstances with additional information (e.g., time of day, weather) to provide actionable information or alerts to the driver of a vehicle, for example. The information or alerts could include, for example, reminders to turn on headlights when there are low light levels. The technology also has the advantage that it can determine vehicle states, vehicle events, and circumstances from a single passive data stream (e.g., voltage in some implementations) and does not require active communication over an OBD-II or a CAN bus. As a result, the determination of events, states, and circumstances is not controlled or constrained by limitations imposed on, for example, information that is made available by a manufacturer from such a bus. In addition, by not connecting through an existing vehicle data bus, there is no risk of unintentional or intentional interference with the operation or state of the vehicle through the device (e.g., by hacking). Also, the technology enables pooling of data streams and other information across multiple (potentially a very large number of) vehicles to refine the ability to identify vehicle states or vehicle events over a wide range of vehicle makes, models, or types.

As shown in FIG. 4, in some examples of a user interface presented by the app at the mobile device in the vehicle, a detected vehicle event, vehicle state, or circumstance can be reported to a driver or other occupant of the vehicle. The report or warning can take the form of a sound, a vibration, or a message on the phone, or another form of presentation, or combinations of two or more of them.

In some cases, vehicle events are associated with physical locations of the vehicle, such as failing to use a turn indicator when making a left-hand or right-hand turn at a particular intersection. In such cases, the app can display a map of the region of the intersection, along with an overlay for the vehicle's trajectory, and an icon indicating the location of the vehicle event. In some embodiments of the user interface, as illustrated in FIG. 4, a score could be provided with respect to a circumstance of the driver's behavior (“How well do you use your signal indicator?”). The user interface of FIG. 4 includes presentation of a map and a trip trajectory showing a location of a missed turn signaling event and a trip-level signaling score.

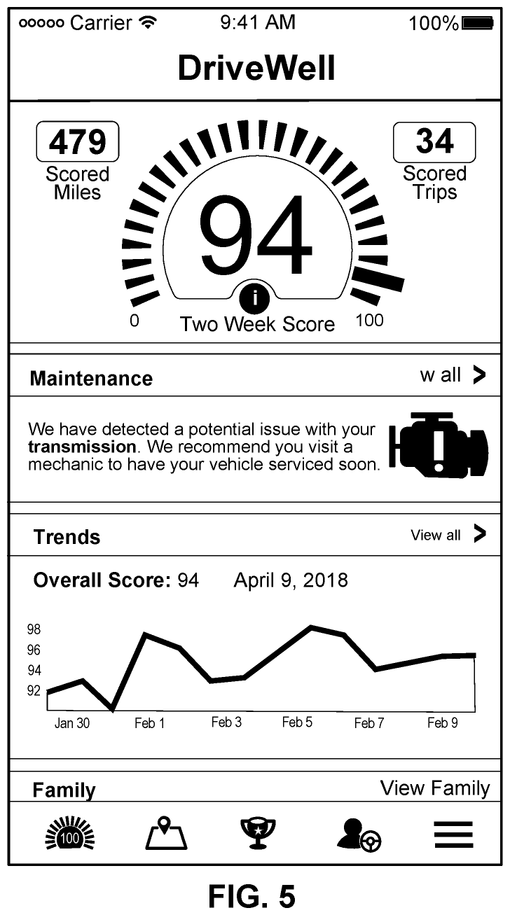

Some vehicle events or vehicle states, particularly vehicle states that persist for some time, can be displayed on the user interface through an in-app card. In some examples, as illustrated in FIG. 5, such a display could warn about a possibly faulty transmission.

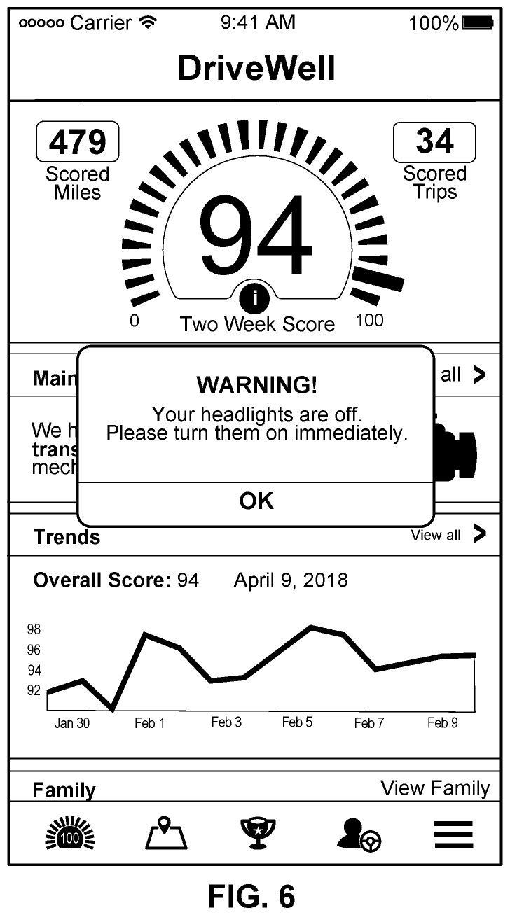

Some vehicle events require more prompt attention and can be more fruitfully displayed through an alert. In some cases, as illustrated in FIG. 6, the alert can tell the driver she has left on the headlights.

The following sections describe how, in some implementations of the technology, battery voltage based detectable vehicle events and vehicle states can be used in combination with other information and a phone app to provide useful information to a driver or other vehicle occupant about circumstances of interest. A wide variety of other circumstances can also be detected and reported.

### Example 1

Many cars on the road do not have headlights that automatically turn on with low ambient light levels, so there is a need for another way to alert a driver when the vehicle headlights are off in such a context.

In some implementations of the technology, the battery voltage sensor collects a sampled stream of battery voltage levels and transmits it to the phone's telematics app. The app monitors and analyzes this data stream to determine if the car's ignition switch is turned on, using a vehicle state or vehicle event detecting method as described above. If the ignition switch is on, then the app detects whether the headlights are off, using a state detecting method as described above. If the headlights are off, the telematics app determines the location of the phone on the Earth (e.g., through a GPS chipset of the phone), and the current time. The app can then compute the solar zenith angle and determine if the light level has dropped below a designated threshold (e.g., if the sun has set). If so, the app can warn the driver of this circumstance and instruct the driver to turn on the headlights. The warning can take the form of a sound, vibration, or message on the phone, or a combination of them. The computation of solar zenith and one or more other steps of the process can take place either on the phone, or the data can be uploaded to the remote server, analyzed remotely, and the app can receive a message from the remote server instructing it to warn the driver or information about the results of one or more of the steps of the process that the app can use in completing the process and warning the driver.

In some embodiments, the app or remote server can perform the above actions and additionally determine the current weather at the location of the vehicle. The weather can be determined, for example, by the phone or the server or both querying a real-time weather server. If the weather indicates that the headlights should be on, a message about the circumstance can be sent to warn the driver. For example, if the weather is raining at any time of day, or the weather is heavily overcast and the sun has nearly set, the app could warn the driver of the circumstance.

In some cases, a wide variety of ambient conditions (weather, temperature, wind, humidity, sunlight, location, and altitude, and combinations of them, for example) can be considered with or combined with a data stream for one or more parameters of the electrical system of a vehicle to form the basis of a determination of a vehicle state or a vehicle event or a circumstance, and an alert or warning or other information can be provided to an occupant of the vehicle or to a variety of third parties who may have an interest.

### Example 2

A car battery is unable to start a car if its stored energy has been depleted below a threshold (e.g., is drained) while the engine is off. Headlights, interior lights, trunk lights, OBD-II devices, stereos, or other accessories left on while the car engine is off (and other causes) can cause battery drain. A car with a drained battery either needs to be jump started from an external power source or replaced.

In some implementations a battery voltage sensor collects a sampled stream of battery voltage levels and transmits it to the phone's telematics app. The app monitors this data stream to determine if the car is turned off, using a vehicle state or vehicle event detection method as described above. After the car is turned off, the sensor continues to measure battery voltage and stream it to the driver's phone for as long as the phone is in range to maintain a Bluetooth (or other wireless) connection. During this period of time (e.g., around 1 minute assuming that the driver leaves the car after turning off the engine), the phone processes the sensor data. If the app detects the circumstance of an excess battery current drain event it warns the driver to check for and correct the cause of battery drain. The warning can take the form of a sound, vibration, or message on the phone or combinations of them. The app continues to monitor the sensor data stream (as long as the app is receiving the data stream) until it no longer detects the circumstance of excess battery current drain, and then notifies the driver they have fixed the issue.

In some implementations, a wide variety of circumstances can be determined and reported by a combination of a vehicle state or vehicle event and information obtained from other sources at the mobile device or an external source about a related context, such as a passage of time or a behavior of a driver.

### Example 3

Unlocked cars lead to theft of cars and personal items left in them. Reducing the opportunity for theft therefore reduces the personal and insurance liability associated with it. The technology can determine that a car is unlocked and warn the driver about that circumstance.

In some implementations, the battery voltage sensor collects a sampled stream of battery voltage levels and 3-axis acceleration data and transmits it to the phone's telematics app. The app monitors the voltage data stream to determine if the car is turned off, using a vehicle state or vehicle event detection method as described above. After the car is turned off, the app monitors the accelerometer data stream to determine when the driver exits the vehicle and closes the door, using one of the previously described event detection methods. Next the app sets an internal timer for some time T (e.g., 15 seconds during which the driver may be expected to remain at the location of the car). If at the end of the timer duration, the app has not detected a power locks activated event from the battery voltage data stream, it issues a warning about the circumstance to the driver to lock the vehicle doors. The warning can take the form of a sound, vibration, or message on the phone, or a combination of them.

In some implementations, a wide variety of risks can be determined and reported by a combination of a vehicle state or vehicle event and information obtained from other sources at the mobile device or an external source about a related risk-related context, such as a passage of time or a behavior of a driver. Another example is the following.

### Example 4

Open windows in an unoccupied vehicle provide an opportunity for theft and weather damage. The technology can provide a driver or other occupant of a vehicle with reminders to secure the windows.

In some examples, first, the battery voltage sensor collects a sampled stream of battery voltage levels and transmits it to the phone's telematics app. The app monitors this data stream to determine if the car's engine is running, using a vehicle state or vehicle event detecting method as described above. If the car's engine is running, then the app detects whether the power windows are operated, using an event detecting method as described above. If, while the car engine is running, a power windows operated event occurs, the app sets a programmable variable flag. Then, when the app detects that the engine is turned off, it checks if the windows flag is set. If the flag is set, the app issues a warning to the driver about the circumstance and suggests to the driver to check that all windows are closed. The warning can take the form of a sound, vibration, or message on the phone, or a combination of them.

### Example 5

An improperly functioning vehicle transmission leads to poor vehicle performance and eventual transmission failure. The technology can detect and report transmission circumstances to reduce maintenance costs and prevent dangerous driving situations.

In some examples, first, the battery voltage sensor collects a sampled stream of battery voltage levels and transmits it to the phone's telematics app. The app monitors this data stream to determine if the car's engine is running, using a state or event detecting method as described above. Once the car's engine is running, the app transmits a command to the battery voltage sensor to continuously calculate and transmit the frequency content of the voltage signal. The sensor measures the battery voltage at a high frequency (e.g. 20 KHz or greater) and stores the values to a memory buffer of size S over time period T. A typical value for T is between 0.1 and 0.01 seconds, and is programmable depending on system requirements. When the buffer is full, the sensor processes the chunk of data to extract the frequencies present. Each chunk of data is processed through a bandpass filter to remove any component of the data stream signal not due to the alternator, and then through a Fast Fourier Transform (FFT) to identify the primary frequency components in the signal. The filter and FFT calculations are implemented in the sensor firmware using standard, widely available algorithms. The resulting calculated frequencies are linearly proportional to the alternator RPM. The alternator RPM is linearly proportional to the engine RPM. The primary measured frequencies are transmitted to the phone every T seconds.

While the engine is running, the telematics app continuously stores the vehicle speed (e.g., based on information provided by a GPS chipset) and the current time. The app transmits the vehicle speed, battery voltage frequency, and timestamp data streams to a remote server either in real time or after a trip is completed. The resulting information is a two-dimensional dataset containing vehicle speed and battery frequency pairs at specific points in time. During any time span when the vehicle does not switch gears, there is a linear and positive relationship between speed and battery frequency (i.e., an increase in vehicle speed corresponds to a proportional increase in voltage frequency.) Discontinuities in the frequency data indicate a vehicle gear shift. The speed at these gear shifts and the duration of the each of the gear shifts is noted and tabulated to form a new dataset containing a list of speeds at which gear changes occur and how long it took for the shift. In a well-functioning transmission, the gear shifts should occur in a consistent, predictable way. Using the vehicle state and vehicle event detection methods described above, this data is compared to a typical data set to determine if there is a potential transmission circumstance. If a transmission circumstance is detected by the server (or in some implementations at the mobile device), it transmits a message to the telematics app which in turn alerts the driver to have the transmission checked by a mechanic. The alert can take the form of a sound, vibration, or message on the phone or a combination of them.

By combining data streams from sensors of the electrical system with data streams representing ambient conditions, such as the passage of time, the technology can determine a wide variety of maintenance and safety and other circumstances and provide alerts to the driver or third parties such as insurance companies, the manufacturer, or maintenance facilities.

### Example 6

Many drivers fail to use a car's turn signals properly when turning, leading to unsafe driving. The technology can determine such behavior and present it to a variety of interested parties such as insurance companies that may use this information to assess driver risk. And telematics apps may provide user feedback to attempt to change this negative behavior.

In some implementations, first, the battery voltage sensor collects a sampled stream of battery voltage levels and transmits it to the phone's telematics app. The app monitors this data stream to determine if the car's engine is running, using a vehicle state or vehicle event detecting method as described above. If the car's engine is running, then the app determines when the turn signals are on, using a vehicle state or vehicle event detecting method as described above. When the turn signal is detected as on, the app stores the time the event or state is detected. This results in a list of times, Tsignal-detected, where the app detected the turn signal.

Simultaneously to monitoring the battery voltage stream, the app also continuously records its location on Earth (e.g. using its GPS receiver.) At the end of a trip, the location data stream is sent to a remote server that analyzes the data to determine the most likely route the vehicle took. (See U.S. Pat. No. 9,228,836, issued Jan. 5, 2016, and incorporated here by reference in its entirety.) This route data is then analyzed to determine the locations, and corresponding timestamps, when the driver should have used the turn signals (e.g. all the times the car changes the road it is on.) This results in a list of times, Tsignal-expected, where the turn signal should have been used.

The app sends the list Tsignal-detected to the remote server. The remote server compares Tsignal-expected and Tsignal-detected to determine any times when the driver did not use a turn signal but should have. These locations and times (circumstances) are stored and used in various ways. They can contribute to an overall driver safety score or be used to send a notification through the app to the driver to encourage behavior change.

A wide variety of other applications can combine data streams from the electrical system with location information to make determinations about driver behavior and risk circumstances and then report the determinations to the driver, an insurance company, or other interested parties.

### Example 7

Using only the battery voltage sensor, the technology can estimate vehicle miles traveled. As discussed in the previous section, there is a linear relationship between the frequency component of the battery voltage signal and engine RPM. For each vehicle gear, there is a linear relationship between engine RPM and vehicle speed. Therefore if the gear number and the battery voltage frequency is known, then the vehicle is speed is known. Integrating the vehicle speed provides an estimate of vehicle miles traveled.

In some instances, when the vehicle is in motion, the battery voltage sensor calculates the primary signal frequency as discussed in the previous section. This data stream and 3-axis acceleration data is transmitted to the driver's phone over Bluetooth or another short-range wireless channel, where it is stored along with vehicle speed data. After a trip has been completed, these three data streams are transmitted to a remote server for processing or in some cases the information is processed at the mobile device.

The data processing objective is to calculate the relationship between the vehicle speed and battery voltage frequency at each vehicle gear. The gear that the vehicle is in at all points in the data is calculated. Each gear shift is located by finding discontinuities in the frequency (see previous section). At each gear shift, the direction (e.g. to a higher or lower gear) is determined. If the new frequency is greater than the previous frequency, the gear shifted lower. If the new frequency is less than the previous frequency, the gear shifted higher.

The gear level is known at all points in time by assuming that the vehicle starts in 1st gear when it begins moving and then incrementing or decrementing the gear level with the previous rules. With this information, the function V=f(Bfrequency, G), where V is vehicle velocity, Bfrequency is battery frequency, and G is gear number, is calculated using standard curve fitting and regression techniques. Over time, as more vehicle data is gathered from multiple drives, this function is consistently revised to increase certainty and is stored in a database entry associated with a specific vehicle or a model of vehicle.

In certain instances, the driver's phone may not be present or may not be connected to the battery voltage sensor. In this case, the sensor behaves the same but it stores the frequency and accelerometer data along with timestamps to its external memory in a log file instead of transmitting it to a phone. The next instance the sensor connects to the driver's phone, it transmits this log file to the phone's telematics app. The app uploads the log file to a remote server for processing (or performs the processing itself) and to calculate the vehicle miles traveled during the time that the sensor was not connected to the phone.

The server uses the previously calculated relationship between battery voltage frequency and gear number to calculate the vehicle velocity at all points in time during the drive. The battery voltage frequency is directly known from the log file. The gear number is estimated with the following method. The vehicle is assumed to be in 1st gear when it initially begins to move. The accelerometer values are used to indicate vehicle movement versus the engine changing its idling frequency. At any point in the data where there is a discontinuity in the battery voltage frequency while the vehicle is in motion, it is assumed that the discontinuity indicates a shift in gears. At each gear shift, the direction (e.g. to a higher or lower gear) is determined. If the new frequency is greater than the previous frequency, the gear shifted lower. If the new frequency is less than the previous frequency, the gear shifted higher. Finally, at each time step the vehicle velocity is calculated from battery frequency and gear level. The list of vehicle velocities is integrated using the data timestamps to estimate the circumstance of a total vehicle miles traveled for the trip.

Other implementations are also within the scope of the following claims.

1. An apparatus comprising
a sensor electrically coupled to terminals of a battery located in a vehicle and connected to an electrical system of the vehicle, the sensor being configured to sense voltages at the terminals of the battery,
a wireless communication device,
a processor, and
a memory to store instructions executable by the processor to
(a) access values of voltages at the terminals of the battery sensed by the sensor,
(b) control a variable frequency at which the values of the voltages are accessed, and
(c) cause the wireless communication device to communicate information about the values of voltages at the terminals of the battery to a mobile device in the vicinity of the vehicle for determination of a locked or unlocked state of a door or an open or closed state of a window of the vehicle based on the values of voltages and based on known events or states corresponding to historical series of values of voltages at terminals of batteries of one or more vehicles and for delivery of an alert of the state of the door or the state of the window through a user interface of the mobile device.

2. (canceled)

3. (canceled)

4. The apparatus of claim 1 further comprising an app of a mobile device in the vehicle.

5. The apparatus of claim 1 further comprising a server.

6. (canceled)

7. The apparatus of claim 1 in which the determined event or state is communicated to a third party, the third-party being remote from the vehicle.

8. The apparatus of claim 1 in which the instructions are executable by the processor to access values of a parameter other than of the electrical system of the vehicle.

9. The apparatus of claim 8 in which the parameter other than of the electrical system of the vehicle comprises a location, an acceleration, a route, a gear level, or a temperature.

10. The apparatus of claim 8 in which the instructions are executable by the processor to identify a circumstance involving the vehicle or an occupant of the vehicle based on the values of the voltages and the values of the parameter other than of the electrical system of the vehicle.

11. The apparatus of claim 10 in which the circumstance involves at least one of convenience, risk, safety, maintenance, and driver behavior.

12. The apparatus of claim 10 in which the circumstance comprises at least one of a circumstance involving battery drainage, transmission performance, and distance traveled.

13. The apparatus of claim 10 in which the instructions are executable by the processor to provide a report or alert of the circumstance.

14. (canceled)

15. The apparatus of claim 1 in which the sensor is configured to provide values of the voltages at a rate lower than the rate at which the sensor senses the values.

16. The apparatus of claim 15 in which the sensor is configured to provide the values wirelessly for access by the processor.

17. (canceled)

18. The apparatus of claim 13 in which the instructions are executable by the processor to provide the report or alert through the user interface or another user interface.

19. An apparatus comprising
a connector coupled electrically to a battery located in and connected to an electrical system of a vehicle,
circuitry connected to sense voltages appearing at the connector,
a wireless communication device, and
a processor in operable communication with the circuitry and the wireless communication device and configured to access values of voltages at the terminals of the batteries by the sensor, control a variable frequency at which the values of the voltages are accessed, and cause the wireless communication device to communicate information about the values of voltages at the terminals of the battery to a mobile device in the vicinity of the vehicle for determination of a locked or unlocked state of the door or an open or closed state of a window of the vehicle based on the values of voltages and based on the values of voltages and on known events or states corresponding to historical streams of values of the voltages and for delivery of an alert of the state of the door or the state of the window through a user interface of the mobile device.

20. (canceled)

21. The apparatus of claim 19 in which the produced information is based on values of the voltages appearing at a rate lower than the rate at which the time series of values are sensed.

22. A method comprising
receiving wirelessly at a mobile device information about voltages at terminals of a battery located in and connected to an electrical system of a vehicle,
determining a locked or unlocked state of a door or an open or closed state of a window of the vehicle based on the received information about the voltages and based on known events or states corresponding to historical streams of values of the voltages, and
communicating the locked or unlocked state of the door or an open or closed state of a window as an alert through a user interface of the mobile device to an occupant of the vehicle.

23. (canceled)

24. (canceled)

25. (canceled)

26. The method of claim 22 further comprising accessing values of a parameter other than of the electrical system of the vehicle.

27. The method of claim 26 in which the parameter other than of the electrical system of the vehicle comprises a location, an acceleration, a route, a gear level, or a temperature.

28. The method of claim 26 further comprising identifying a circumstance involving the vehicle or an occupant of the vehicle based on the values of the voltages and the values of the parameter other than of the electrical system of the vehicle.

29. The method of claim 28 in which the circumstance involves at least one of convenience, risk, safety, maintenance, and driver behavior.

30. The method of claim 28 in which the circumstance comprises at least one of a circumstance involving battery drainage, transmission performance, and distance traveled.
